(19) United States
(12) Patent Application Publication
(10) Pub. No.: US 2026/0229282 A1
(43) Pub. Date: Aug. 6, 2026

(54) SRAM ARCHITECTURE FOR ULTRA-LOW ARRAY LEAKAGE IN SHUT DOWN MODE

(71) Applicant: STMicroelectronics International N.V., Geneva (CH)

(72) Inventors: Sant Swaroop SHRIVASTAVA, AGRA (IN); Praveen Kumar VERMA, GREATER NOIDA (IN)

(21) Appl. No.: 19/465,656

(22) Filed: Jan. 30, 2026

Related U.S. Application Data
(60) Provisional application No. 63/752,955, filed on Feb. 3, 2025.

(51) Int. Cl. G11C 11/417; G11C 11/412; G11C 11/419; H10B 10/00

(52) U.S. Cl. CPC G11C 11/417; G11C 11/412; G11C 11/419; H10B 10/12; H10B 10/18

(57) ABSTRACT

Apparatuses, systems, and methods for SRAM architecture for reduced array leakage in a shutdown mode are provided. An example SRAM memory device includes one or more memory cores, each with multiple bit cells arranged in column slices. Each column slice is associated with its own header circuitry and footer circuitry. The header circuitry is configured to control the operational mode of the column slice. Each footer circuitry includes a footer switch. A top side of the footer switch is connected to a VSSC of the bit cells and a PWELL region of the associated column slice. A bottom side of the footer switch is connected to ground. A shutdown signal operates the footer switch to open the switch or close the switch, which would connect VSSC and the PWELL region to ground.

CROSS REFERENCE TO RELATED APPLICATION(S)

This application claims priority to U.S. Provisional Patent Application No. 63/752,955 filed on February 3, 2025, which is incorporated herein by reference in its entirety.

### TECHNOLOGICAL FIELD

### BACKGROUND

Example embodiments of the present disclosure relate generally to static random access memory (SRAM), particularly to an SRAM architecture for reduced array leakage in shut down mode.

Static random access memory (SRAM) is used in electronics due to its ability for quick data access. Contemporary electronics and applications (e.g., Internet of Things (IoT), wearables, low power devices, and other applications) have created a growing demand for low power devices that can operate for extended periods of time on a single battery charge. Many of these contemporary electronics and applications include a device operating in a low power mode or a shut down mode to conserve battery power. Conventional SRAM memories have excess leakage, including when the SRAM memories may be operating in a shut down mode with the SRAM memory not being actively used.

The inventors have identified numerous areas of improvement in the existing technologies and processes, which are the subjects of embodiments described herein. Through applied effort, ingenuity, and innovation, many of these deficiencies, challenges, and problems have been solved by developing solutions that are included in embodiments of the present disclosure, some examples of which are described in detail herein.

### BRIEF SUMMARY

Various embodiments described herein relate to methods, apparatuses, and systems for SRAM memories, particularly to SRAM memory architectures for ultra low array leakage in shut down mode.

In accordance with some embodiments of the present disclosure, an example SRAM memory device is provided. The SRAM memory device comprising: one or more memory cores, wherein each memory core comprises a plurality of column slices of bit cells, and wherein each of the column slices of bit cells comprises a plurality of bit cells; one or more footer switch circuitries, wherein each of the one or more footer switch circuitries is associated with a single column slice of bit cells of the plurality of column slices of bit cells, and wherein each of the one or more footer switch circuitries comprises a footer switch; and wherein each footer switch comprises a footer transistor, wherein each footer transistor comprises a footer transistor drain, a footer transistor gate, and a footer transistor source; and wherein each footer circuitries is configured with: the footer transistor drain of the footer transistor electrically connected to a bit cell source voltage line of a plurality of bit cells and a PWELL region of the associated single column slice of bit cells; the footer transistor source of the footer transistor electrically connected to ground; and the footer transistor gate of the footer transistor configured to receive a shutdown signal to operate, in a shutdown mode, the footer transistor as a switch to electrically connect the bit cell source voltage line of the plurality of bit cells and the PWELL region of the associated single column slice of bit cells with ground.

In some embodiments, the SRAM memory, in the shutdown mode, is configured to reduce a forward body bias of the PWELL region of the associated single column slice of bit cells.

In some embodiments, the SRAM memory, in a shutdown mode, is configured for the plurality of bit cells of each column slice to be corrupted and not retain a memory content of each bit cell.

In some embodiments, the SRAM memory device further comprising one or more header circuitries, wherein each header circuitry is associated with one of the single column slices of bit cells.

In some embodiments, each of one or more header circuitries is comprised of a plurality of transistors configured to operate the SRAM memory device in a functional mode, retention mode, and shutdown mode.

In some embodiments, the plurality of bit cells of each column slice are arranged in a plurality of bit cell rows and a plurality of bit cell columns.

In some embodiments, the one or more memory cores include a first memory core and a second memory core arranged in a butterfly configuration.

In some embodiments, each memory core is comprised of a PWELL region surrounded by an NWELL region.

In some embodiments, the NWELL region is comprised of an external NWELL region and an internal NWELL region, wherein the internal NWELL region is adjacent to a control circuitry.

In some embodiments, the SRAM memory device is in an Internet-of-Things device.

In accordance with some embodiments of the present disclosure, an example method is provided. The method comprising: providing a memory device comprising: one or more memory cores, wherein each memory core comprises a plurality of column slices of bit cells, and wherein each of the column slices of bit cells comprises a plurality of bit cells; one or more footer switch circuitries, wherein each of the one or more footer switch circuitries is associated with a single column slice of bit cells of the plurality of column slices of bit cells, and wherein each of the one or more footer switch circuitries comprises a footer switch; wherein each footer switch comprises a footer transistor, wherein each footer transistor comprises a footer transistor drain, a footer transistor gate, and a footer transistor source; and wherein each footer circuitries is configured with: the footer transistor drain of the footer transistor electrically connected to a bit cell source voltage line of a plurality of bit cells and a PWELL region of the associated single column slice of bit cells; the footer transistor source of the footer transistor electrically connected to ground; and the footer transistor gate of the footer transistor configured to receive a shutdown signal to operate, in a shutdown mode, the footer transistor as a switch to electrically connect the bit cell source voltage line of the plurality of bit cells and the PWELL region of the associated single column slice of bit cells with ground; receiving a shutdown signal at at least one first footer switch of the plurality of footer switches to operate the at least one first footer switch to connect the bit cell source voltage line of a plurality of bit cells associated with the at least one first footer switch to ground.

In some embodiments, the method further comprises, in the shutdown mode, reducing a forward body bias of the PWELL region of the associated signal column slice of bit cells.

In some embodiments, the method further comprises in the shutdown mode, corrupting the plurality of bit cells of each column slice and not retaining a memory content of each bit cell

In some embodiments, the memory device further comprises one or more header circuitries, wherein each header circuitry is associated with one of the single column slices of bit cells.

In some embodiments, each of one or more header circuitries is comprised of a plurality of transistors configured to operate the SRAM memory device in a functional mode, retention mode, and shutdown mode.

In some embodiments, the plurality of bit cells of each column slice are arranged in a plurality of bit cell rows and a plurality of bit cell columns.

In some embodiments, the one or more memory cores include a first memory core and a second memory core arranged in a butterfly configuration.

In some embodiments, each memory core is comprised of a PWELL region surrounded by an NWELL region.

In some embodiments, the NWELL region is comprised of an external NWELL region and an internal NWELL region, wherein the internal NWELL region is adjacent to a control circuitry.

In some embodiments, the SRAM device is in an Internet-of-Things device.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

Having thus described certain example embodiments of the present disclosure in general terms, reference will now be made to the accompanying drawings, which are not necessarily drawn to scale, and wherein:

FIG. 1 illustrates an exemplary SRAM memory in accordance with one or more embodiments of the present disclosure;

FIG. 2 illustrates an exemplary PWELL structure and NWELL ring in Deep NWELL structure in accordance with one or more embodiments of the present disclosure;

FIG. 3 illustrates an exemplary column slice in accordance with one or more embodiments of the present disclosure;

FIG. 4 illustrates an exemplary bit cell in accordance with one or more embodiments of the present disclosure;

FIG. 5 illustrates a first example of column slice circuitry in accordance with one or more embodiments of the present disclosure;

FIG. 6 illustrates a first example of peripheral circuitry in accordance with one or more embodiments of the present disclosure;

FIG. 7 illustrates a second example of column slice circuitry in accordance with one or more embodiments of the present disclosure; and

FIG. 8 illustrates a flowchart of operations in accordance with one or more embodiments of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in various embodiments,” “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments or it may be excluded.

### Overview

Various embodiments described herein relate to methods, apparatuses, and systems for SRAM memories, particularly SRAM memory architectures.

Static random access memory (SRAM) is used in electronic devices and applications (e.g., Internet of Things (IoT) devices, wearables, low power devices, and other applications) to operate as or in low power devices. These low power devices may operate for extended periods of time on a single battery charge. These devices may have multiple modes of operation, such as functional mode(s), standby mode(s), sleep mode(s), retention mode(s), and/or a shut down mode.

A functional mode or normal mode may have the SRAM memory providing read and write functionality to access or store data in the SRAM memory.

A standby mode may have the SRAM memory going into standby while waiting to receive an instruction for an operation to be performed.

A retention mode may have the SRAM memory in a low(er) power state while allowing for retaining data in the SRAM memory.

A shutdown mode is used when retaining data is not required and may also include the data being purged. In shut down mode, a device may continuing to utilize some logic or control while ceasing other operations to save power. An exemplary electronic device may be a System on a Chip (SoC). An application running on an SoC in a shut down mode may operate but most of the logic on the SoC, including the memory, are shut down and not functional. The shut down mode may cut leakage of the SRAM as much as possible even while a device is always on (e.g., an IoT device). An exemplary device may be an IoT device with a battery that is used for power but is intermittently or rarely charged. Various embodiments may be ultra-low power SRAM memories.

An example of when a shutdown mode may be used may include a device with a wakeup or watchdog mode in which the device or system is operating at a very low power and performance mode just to receive a signal(s) for the device to wakeup. Such devices may use such modes to preserve, among other things, battery life.

Embodiments of the present disclosure include architectures for SRAM memory for such devices and/or applications. Various embodiments provide for reduced memory array leakage in a shutdown mode, which may be referred to as shutdown mode leakage. Various embodiments may reduce shutdown mode leakage with a self-biasing of bit cells and/or logic wells. This may provide a reverse bias without the help of any external body bias generation.

### Exemplary Systems, Apparatuses, and Methods

Embodiments of the present disclosure herein include methods, apparatuses, and systems for SRAM memory architectures.

FIG. 1 illustrates an exemplary SRAM memory or SRAM memory device in accordance with one or more embodiments of the present disclosure. The SRAM memory device 100 includes a first memory core 110A, a second memory core 110B, external NWELL isolation region 122 (e.g., 122A, 122B), internal NWELL isolation region 124 (e.g., 124A, 124B), and control circuitry 140. In the embodiment illustrated in FIG. 1, the SRAM memory device 100 has a butterfly architecture with a first memory core 110A on a first side of the SRAM memory device 100 and a second memory core 110B on an opposite, second side of the SRAM memory device 100. The first memory core 110A and the second memory core 110B are separated by, among other things, a portion of the control circuitry 140. In various embodiments, the control circuitry 140 may be referred to as peripheral logic or peripheral circuitry as it is located around the peripheral of the memory core(s) 110.

A memory core 110 includes a bit cell region 112 and driver PMOS circuitry region 130. For example, the first memory core 110A includes a first bit cell region 112A and first driver PMOS circuitry region 130A. The second memory core 110B includes a second bit cell region 112B and a second driver PMOS circuitry region 130B. Driver PMOS circuitry region 130A includes a first driver PMOS circuitry 132A, a second driver PMOS circuitry 132B, a third driver PMOS circuitry 132C, and a fourth driver PMOS circuitry 132D. Driver PMOS circuitry region 130B includes a fifth driver PMOS circuitry 132E, a sixth driver PMOS circuitry 132F, a seventh driver PMOS circuitry 132G, and an eighth driver PMOS circuitry 132H.

The bit cell region 112 includes a plurality of bit cells, which is where memory content is stored. A bit cell is the memory cell that stores and preserves datum. The bit cell regions 112 collectively store the data that is stored in the SRAM memory device 100.

The control circuitry 140 includes multiple types of circuitry to control the writing and reading of the memory core(s) 110. The control circuitry 140 may include row decoder circuitries 142 and input-output circuitries 144. The control circuitry 140 may also include circuitry for controlling the row decoder circuitries 142 and the input-output circuitries 144. Each memory core 110 (e.g., 110A, 110B) of the SRAM memory device 100 is driven separately by the control circuitry 140 to reduce resistance and/or capacitance.

In various embodiments, there may be a row decoder circuitry 142 associated with each driver PMOS circuitry 132 of a memory core 110. For example, a first row decoder circuitry 142A is associated with first driver PMOS circuitry 132A and fifth driver PMOS circuitry 132E. A second row decoder circuitry 142B is associated with second driver PMOS circuitry 132B and sixth driver PMOS circuitry 132F. A third row decoder circuitry 142C is associated with third driver PMOS circuitry 132C and seventh 132G. A fourth row decoder circuitry 142D is associated with fourth driver PMOS circuitry 132D and eighth driver PMOS circuitry 132H. It will be appreciated that various embodiments may include more row decoder circuitry 142 than illustrated in FIG. 1.

In various embodiments, there may be multiple input-output circuitries 144 for each bit cell region 112. For example, there may be a first input-output circuitry 144A and a second input-output circuitry 144B associated with a first bit cell region 112A. There may be a third input-output circuitry 144C and a fourth input-output circuitry 144D associated with a second bit cell region 112B. Each input-output circuitry 144 may be associated with a unique set of bit cells in one or more columns in a bit cell region 112 of a memory core 110. It will be appreciated that various embodiments may include more input-output circuitries 144 than illustrated in FIG. 1.

In various embodiments, the bit cell region 112 may include both an NMOS region(s) and a PMOS region(s) providing for a single well for each bit cell. The NMOS region(s) and PMOS region(s) may be of the same well potential, and because of this there may be advantages and challenges. For example, the PMOS of the PMOS region(s) is forward biased because in the bulk technology PMOS is connected to drain supply voltage (VDD) and the NMOS of the NMOS region(s) is connected to ground (GND). Since the forward biased PMOS may be heavily leaking, then the SRAM memory device 100 may be heavily leaking because it is forward biased by the configuration in which the NMOS region(s) is connected to ground (GND).

The bit cell region 112 includes transistors of multiple types, including N-type transistors and P-type transistors. Both the N-type and P-type transistors are sharing the single well connections, which has the forward bias PMOS.

The driver PMOS circuitry region 130 is a buffer, which may be a final buffer before the row decoder circuitry 142. The driver PMOS circuitry region 130 may share by the same memory array supply voltage (VDDMA), such as in a dual rail configuration where memory periphery supply voltage (VDDMP) and memory array supply voltage (VDDMA) are at different voltage potentials. This may provide for gain power as the SRAM memory device 100 is sensitive to power because of being used in low power applications.

To reduce the overall power, the SRAM memory (as well as other portions of an application, such as a SoC) is operating at a lower voltage. Thus, an interface of the SRAM memory device 100 communicating with application circuitry (e.g., SoC circuitry) is sitting at the lower potential. For example, memory periphery supply voltage (VDDMP) is the peripheral voltage and it is aligned to the application potential (e.g., a SoC potential). But there may also be another memory supply voltage (VDDMS) and another memory array supply voltage (VDDMA), which are working at higher potentials. In the embodiment illustrated in FIG. 1, there is a split configuration where the control circuitry 140 at the periphery of the SRAM memory device 100 operates at the application potential (e.g., potential aligned to an SoC) of memory periphery supply voltage (VDDMP) while the memory array of the memory core(s) 110 is working at a higher potential of memory array supply voltage (VDDMA) to secure the functionality of the bit cells or memory cells.

Since the memory core(s) 110 is operating at a higher potential there is a level shifter which shifts the higher potential and then a word line (WL) is then eventually driven to the memory array supply voltage (VDDMA) potential.

Region outside the pocket created by 122 and 124 NWELL ring is periphery logic and may receive forward bias on its wells (NWELL and PWELL pockets other then 112) to boost performance of periphery logic. And to avoid the forward bias being applied to the core of the SRAM memory device 100, an isolation region(s) 112 is provided. For example, each memory core 110 may have an NWELL ring isolation region 122 and an internal NWELL isolation region 124. The external NWELL isolation region 122 may provide isolation to the exterior of the memory core 110. The internal NWELL isolation region 124 may provide isolation to the internal portion of the SRAM memory device 100, such as the control circuitry 140. The isolation by the internal NWELL isolation region 124 allows for the memory core(s) 110, including the bit cell region 112 and driver PMOS circuitry region 130, to be operated at a higher voltage than the control circuitry 140. This electrical isolation allows for the separate voltages to not bias each other outside of specific connections allowing for the storing, reading, and control of the memory core(s) 110. The complete structure is on the Deep NWELL creating PWELL pocket(s) 112 for core region and PWELL pocket(s) for periphery 140 (not illustrated).

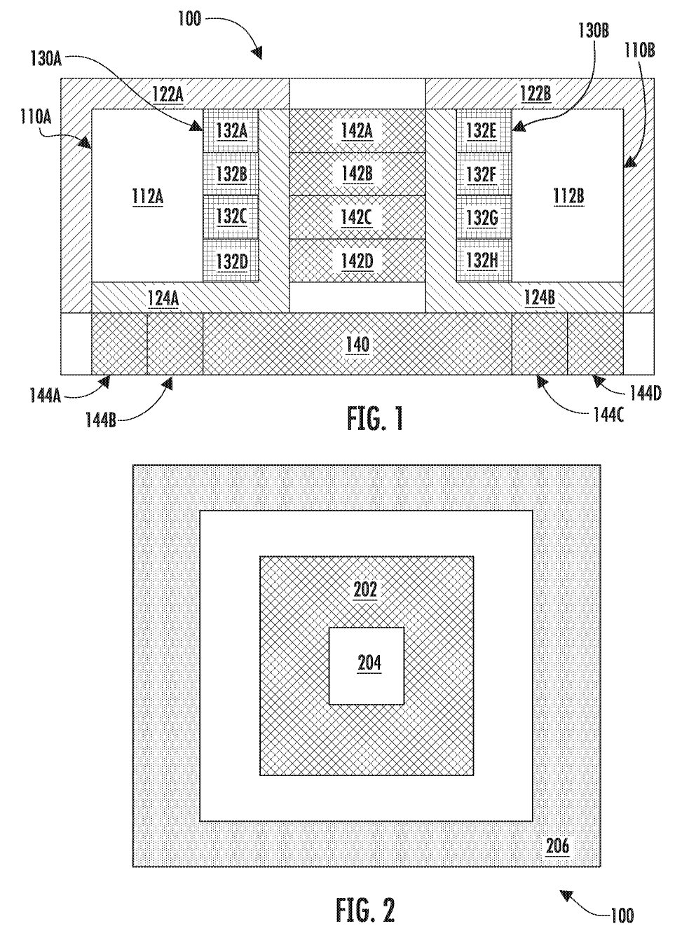

FIG. 2 illustrates an exemplary PWELL region and NWELL region in Deep NWELL in accordance with one or more embodiments of the present disclosure. A memory cell in a memory core 110 includes both NMOS transistor and a PMOS transistor in the same PWELL receiving the same bias. The NWELL region 202 is used to create a ring surrounding the PWELL pocket of a PWELL region 204 of the memory core 110. The PWELL region represents bulk of the memory core 110 having both NMOS and PMOS transistors. The NWELL region 202 and the PWELL region 204 may have different well potentials. In various embodiments, the PWELL region 204 may be electrically connected to a ground GND and the NWELL region 202 may be electrically connected to ground (GND or GNDMA) or a supply (VDD or VDDMA) depending on the forward bias condition. In an example, this has the NWELL region 202, particularly the internal NWELL isolation region 124, keeping the periphery region at 0 voltage or 0 potential. The PMOS of the PWELL region 204 is forward biased, which results in the leakage.

The NWELL region 202 and the PWELL region 204 are surrounded by a Deep NWELL region 206. The NWELL region 202 and the PWELL region 204 may be surrounded by the Deep NWELL region 206 and also be on a layer above the Deep NWELL region 206. Due to the Deep NWELL region 206, the NWELL region 202 that rings around the core and the NWELL on periphery are on same potential. The forward body bias on the periphery will modulate the voltage potential on an external NWELL isolation region 122 and internal NWELL isolation region 124. The NMOS transistors and the PMOS transistors are in same PWELL region 204 which is normally on zero potential during function, which makes the SRAM PMOS devices FBB even if FBB on periphery is zero.

FIG. 3 illustrates an exemplary column slice in accordance with one or more embodiments of the present disclosure. A memory core 110 is comprised of multiple bit cells 320 arranged in columns and rows. A column slice 310 may be comprised of multiple bit slices, and the bit slices may be comprised of bit cells of multiples of 2. The bit cells 320 and column slice 310 may be arranged in a PWELL region 204 of a memory core 110. One or more columns may be divided into a column slice 310 and/or a row slice. A column slice 310 (or row slice) includes a plurality of bit cells. It will be appreciated that while FIG. 3 illustrates a column slice 310 having 6 bit cells 320, various embodiments may include more or less bit cells 320 per column slice 310 (or row slice).

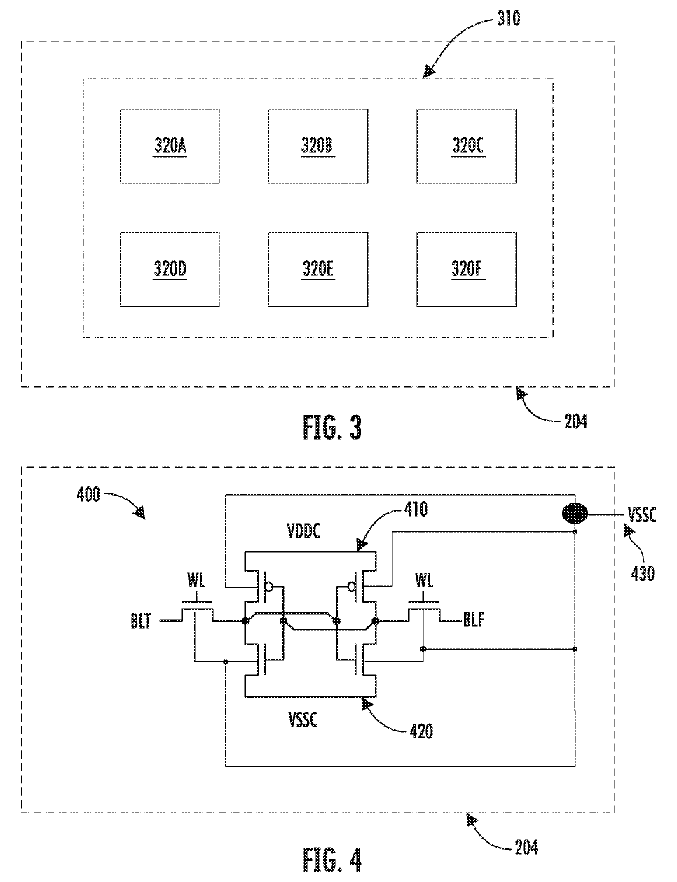

FIG. 4 illustrates an exemplary bit cell in accordance with one or more embodiments of the present disclosure. A bit cell 400 may include a plurality of transistors, including NMOS transistors and PMOS transistors. The bit cell 400 may include a bit cell supply voltage line 410 operating at a bit cell supply voltage (VDDC) and a bit cell source voltage line operating at a bit cell source voltage (VSSC). The bit cell supply voltage (VDDC) may be at a higher voltage potential than the bit cell body or bulk voltage (VSSC). The bit cell 400 illustrated is in a PWELL region 204 of a memory core 110.

In various embodiments, an electrical connection 430 may electrically connect the PWELL region 204 (bulk connection) of the bit cell to ground voltage line 420 to provide the bit cell source voltage (VSSC) from one or more other circuits, such as a footer circuit described herein. It will be appreciated that while a bulk connection to certain transistors is illustrated, the electrical connection 430 may be to a bulk or body connection of each device or transistor.

The PMOS of the PWELL region 204 is forward biased. Because of the forward bias, the resistance of the memory core(s) 110 contribute to the overall system resistance and, thus, leakage. In various embodiments, when VSSC is connected to the PWELL region 204, the potential of the PWELL region 204 is increased. This reduces the forward bias condition of the PMOS. The reduction in the forward bias lowers the effective resistance of the core memory(ies) 110.

While FIG. 4 illustrates a bit cell 400 in a PWELL region 204, various embodiments have an NWELL region 202 with potential that is higher to the footer switch. This will reduce the forward body bias (FBB) of the PMOS. The bulk of the PMOS and the NMOS are connected to the PWELL region 204. In various embodiments, the PMOS will be forward biased with a potential that is almost the same potential as VDDC. As described herein, this potential will raise from the ground when a footer switch is open, and this increase in potential increases the voltage of the PWELL region 204.

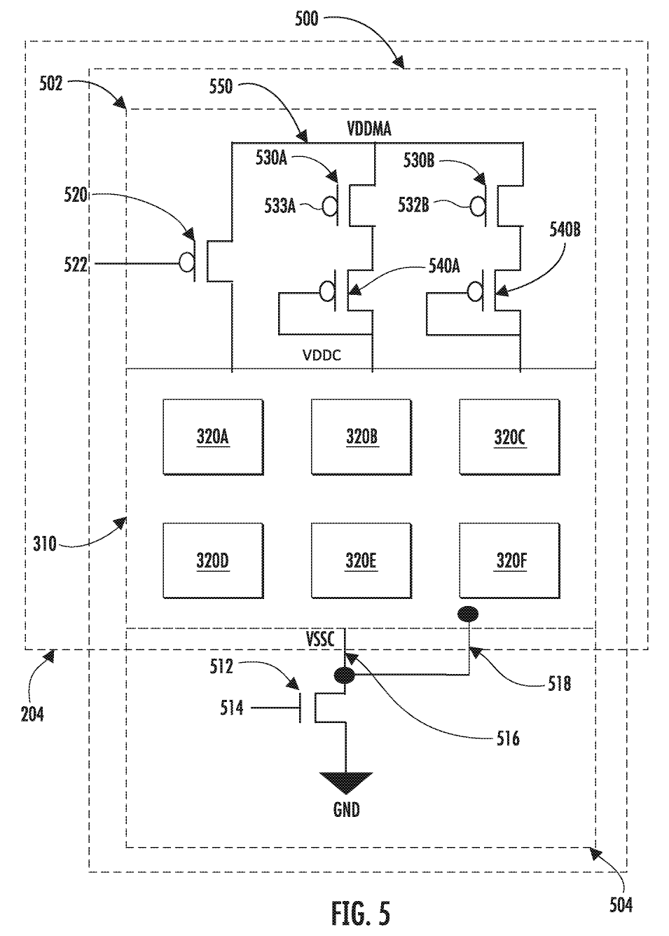

FIG. 5 illustrates a first example of column slice circuitry in accordance with one or more embodiments of the present disclosure. Each column slice 310 includes column slice circuitry 500 that includes header circuitry 502 and footer circuitry 504. Thus, each column slice 310 is associated with its own respective header circuitry 502 and footer circuitry 504.

The column slice 310 may include a plurality of bit cells 320. Each column slice 310 is connected to its respective header circuitry 502 and footer circuitry 504. The header circuitry 502 and footer circuitry 504 are used to control the operations of a column slice to be in one of multiple modes (e.g., functional mode, sleep mode, retention mode, shutdown mode).

The header circuitry 502 may be located above a column slice 310 and provide one or more signals to the column slice 310. A header circuitry 502 may include a plurality of transistors that are used to generate a voltage potential for the column slice 310, particularly the bit cell supply voltage (VDDC) from the memory array supply voltage (VDDMA) of the memory array supply voltage line 550.

In various embodiments, the header circuitry 502 may include three retention transistors in switch configurations (e.g., 520, 530A, and 530B) and two retention transistors in diode configurations (e.g., 540A, 540B). In various embodiments, the header circuitry is connected to a voltage source of memory array supply voltage (VDDMA). A drain of a first retention switch transistor 520, a drain of a second retention switch transistor 530A, and a drain of a third retention switch transistor 530B are connected to the voltage source memory array (VDDMA) voltage at the memory array supply voltage line 550.

A first retention switch control signal 522 to the first retention switch transistor 520 may switch the first retention switch transistor 520 to be either opened or closed. The source of the first retention switch transistor 520 is connected to column slice 310 to provide a voltage. When the first retention switch transistor 520 is operated in a closed position, then the voltage provided is the memory array supply voltage (VDDMA).

A second retention switch control signal 532 to the second retention switch transistor 530A may switch the second retention switch transistor 530A to be either opened or closed. In various embodiments the second retention switch transistor 530A may be associated with a first retention mode. The second retention switch transistor 530A may be configured to receive a second retention switch control signal 532A that controls the operating mode of column slice 310, such as operating in a first or second retention mode.

A third retention switch control signal 532B to the third retention switch transistor 530B may switch the third retention switch transistor 530B to be either opened or closed. In various embodiments the third retention switch transistor 530B may be associated with a second retention mode. The third retention switch transistor 530B may be configured to receive a third retention switch control signal 532B that controls the operation of column slice 310 to operate in a second retention mode.

In various embodiments, the second retention switch control signal 532A and the third retention switch control signal 532B may be used in conjunction to control the column slice 310 entering into a first retention mode or a second retention mode. For example, the second retention switch control signal 532A may be binary with a value of 0 or 1 and the third retention switch control signal 532B may also be binary with a value of 0 or 1. The column slice 310 may be in normal operations when the second retention switch control signal 532A is 1 but change to a retention mode when the second retention switch control signal 532A is 0. The third retention switch control signal 532B may indicate if a first retention mode is used (e.g., value of 0) or a second retention mode is used (e.g., value of 1).

The drain of the second retention switch transistor 530A is connected to a source of a first retention diode transistor 540A. The first retention diode transistor 540A is in a diode configuration with the gate of transistor 540A connected to drain of the first retention diode transistor 540A and to the column slice 310. In various embodiments, the first retention diode transistor 540A may be a first retention diode.

The drain of third retention switch transistor 530B is connected to a source of a second retention diode transistor 540B. The second retention diode transistor 540B is in a diode configuration with the gate of second retention diode transistor 540B connected to drain of second retention diode transistor 540B and to the column slice 310. In various embodiments, the second retention diode transistor 540B may be a second retention diode.

In various embodiments, the voltage between the header circuitry 502 and the column slice 310 is the bit cell supply voltage (VDDC), which is determined by the resistance of the parallel paths through the header circuitry 502.

When no operations are being performed, the first retention switch transistor 520 may be switched off, which connects VDDMA to VDDC.

If the device is not in retention mode but in normal operation, the first retention switch transistor 520 is turned on so that VDDC is equal to VDDMA.

In various retention modes when the first retention switch transistor 520 is turned off and at least one of the retention branches with the second retention switch transistor 530A or the third retention switch transistor 530B is turned on, VDDC may be lowered but not lowered so low as to corrupt data in the memory core 110. This lowering is done by the configuration of the paths through the second retention switch transistor 530A and the first retention diode transistor 540A as well as through the third retention switch transistor 530B and the second retention diode transistor 540B. The voltage level or threshold for lower voltage is such that the diode drop is controlled by the voltage drop across either or both of first retention diode transistor 540A and/or the second retention diode transistor 540B. The respective diode drops are configured to modulate the voltage to the column slice 310 of the memory core 110 while providing flexibility via different retention modes. In various embodiments, the different retention modes may provide flexibility for uncertainty during production. The redundant paths allow for variation in size. The diode size and the leakage of the memory core 110 determine the potential of VDDC when these paths are used.

To enter a shutdown mode, the first retention switch transistor 520, the second retention switch transistor 530A, and the third retention switch transistor 530B are turned off (i.e., closed). Then the data in the column slice 310 will not be retained as the VDDC will be lowered down to a value associated with the resistance of the SRAM core.

The resistance of the header circuitry 502 and of the column slice 310 of the memory core 110 is the effective resistance of the memory device. The potential of VDDC is determined by the resistance of the parallel paths and the column slice 310. The overall system, however, still leaks because it depends on the overall effective resistance associated with the left path with the first retention switch transistor 520.

The footer circuitry 504 may include a footer switch 512, which may be a transistor configured as a switch.

In the present disclosure, footer circuitry 504 of a footer switch 512 is controlled to open or close with a footer switch control signal 514 of a shutdown signal. In various embodiments, the shutdown signal may be the same (or different) from one or more retention signals that operate one or more other transistors (e.g., 520, 530A, 530B, etc.). With the footer switch 512 electrically connected to VSSC as described herein, operation of the footer switch 512 improves leakage.

In various embodiments, the footer switch 512 may be a transistor with its drain electrically connected to the column slice 310 with electrical connection 516 as well as electrically connected to the PWELL region of the column slice 310 with connection 518. The electrical connection 516 connects the footer switch 512 with the source voltage (VSSC) of the bit cell source voltage line 420 of each bit cell 320 of the column slice 310. For example, the bit cell source voltage line 420 of each bit cell 320 of the column slice 310 may be connected in parallel and then connected to the drain of the footer switch 512 with electrical connection 516. The electrical connection 518 to the PWELL region of the column slice 310 ties the footer switch 512 and the potential of the PWELL region to VSSC. The source of the transistor of the footer switch 512 is connected to ground (GND).

The footer switch 512 may be operated in an open state and in a closed state. The operation of the footer switch 512 is with footer switch control signal 514, which is provided to the gate of the transistor of the footer switch 512 to control the state of the footer switch 512. In an open state, the footer switch 512 may isolate the column slice 310 and PWELL region from ground. When VSSC is connected to the PWELL region of the column slice 310, the potential of the PWELL region is increased. This reduces the forward bias condition of the PMOS. The reduction in the forward bias lowers the effective resistance of the SRAM core. In a closed state, the footer switch 512 may connect the column slice 310 and the PWELL region to ground.

In various embodiments, each footer switch 512 of all of the footer circuitries 504 associated with all of the column slices 310 of the memory core(s) 110 are operated simultaneously. For example, each footer switch 512 is closed (or opened) together. During normal operation the footer switch 512 is closed and the VSSC is pulled to zero volts. During shutdown operations, the footer switch 512 is changed to open. In a shutdown mode, the footer switch 512 is operated to open, the VSSC will be raised based on the leakage ratio of the array of the column slice 310 versus the footer switch 512.

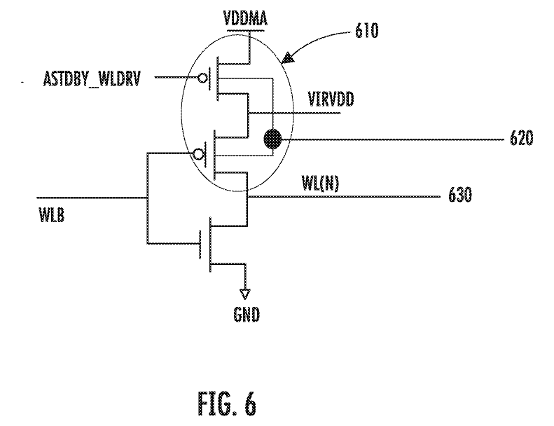

FIG. 6 illustrates a first example of peripheral circuitry in accordance with one or more embodiments of the present disclosure. The peripheral circuitry may be in the control circuitry 140.

In various embodiments, the peripheral circuitry includes, among other things, one or more transistors for controlling the distribution of signals to the memory cores 110. For example, transistors may be used to distribute drive signals and/or data. A standby word line drive signal (ASTDBY_WLDRV) is a standby signal which may be used to generate or transmit a virtual voltage drain (VIRVDD) supply voltage. A word line bus (WLB) voltage signal may be received to generate a word line (WL(N)) voltage signal 630 for one of N word lines, which may be provided to one or more column slices 310. The word line (WL(N)) voltage signal 630 may be used to active a specific row of bit cells for a read or write operation.

The transistors of the peripheral circuitry may include PMOS transistors and NMOS transistors. One or more of the PMOS transistors may be located in a PWELL region 610 of the control circuitry 140. In various embodiments, the PWELL region 610 of the peripheral circuitry may be connected to VSSC, such as with an electrical connection to footer circuitry 504, particularly to a top side of a footer switch 512. In various embodiments, the footer switch 512 is electrically connected to the PWELL region 610 via an electrical connection 620 to the PWELL region 610 of the control circuitry, which may be in place of (or in addition to) electrical connection 518. Thus, in various embodiments, the PWELL region 610 may be a connection to VSSC. It will be appreciated that while a bulk connection to certain transistors is illustrated, the electrical connection 620 may be to a bulk or body connection of each device or transistor.

The control circuitry 140 may be used to generate multiple signals that are provided to, among other things, the column slices 310. Each column slice 310 has its own associated header circuitry 502 and footer circuitry 504, which may receive one or more of the signals generated by the control circuitry 140.

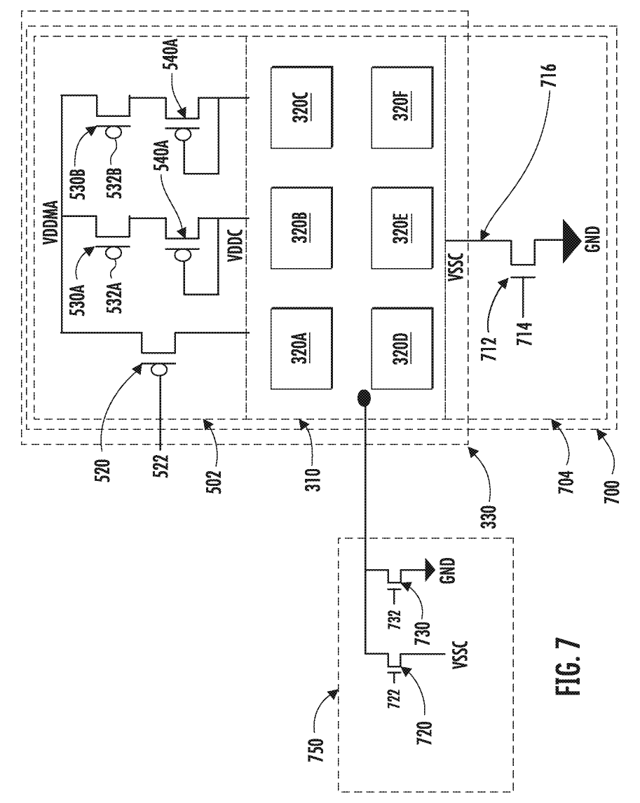

FIG. 7 illustrates a second example of column slice circuitry in accordance with one or more embodiments of the present disclosure.

In the second example, the PWELL region of column slice 310 is connected to two transistors in shutdown switch circuitry 750, a first transistor that is a first shutdown switch 720 and a second transistor that is a second shutdown switch 730. The first shutdown switch 720 may provide an electrical connection to VSSC of the bit cell source voltage line to a PWELL portion of the peripheral circuitry of the control circuitry 140 (e.g., as illustrated in FIG. 5) and the second shutdown switch 730 may provide an electrical connection to ground. Each of these two switches may connect a PWELL region to the VSSC or, alternatively, to ground. In contrast to the first example of FIG. 5, the footer switch 512 of FIG. 7 is not tied directly to the PWELL region of the column slice 310. The footer switch control signal 714 to the footer switch 712 may be the same as a second shutdown switch control signal 732 to the second shutdown switch 730. The first shutdown switch control signal 722 to control the first shutdown switch 720 may be set to be the inverse of the footer switch control signal 714, which is also the inverse of the first shutdown switch control signal 732. Thus the footer switch control signal 714 may control operation of the footer switch 712, the second shutdown switch 730, and the first shutdown switch 720. In various embodiments, during normal mode when footer switch 712 is one PWELL should be at ground and, thus, the footer switch 712 and the second shutdown switch 730 receive the same signal.

The shutdown control signal allows for the switching for turning off the device in parallel to the ground. This provides for turning off the footer switch 712 whenever there is a footer switch control signal 714 of a shutdown signal.

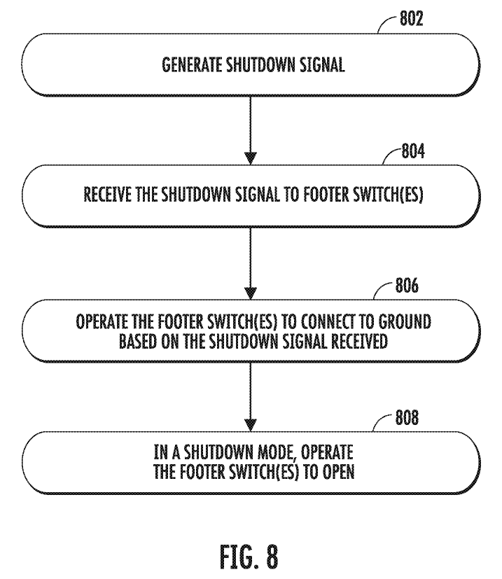

FIG. 8 illustrates a flowchart of operations in accordance with one or more embodiments of the present disclosure.

At operation 802, generate a shutdown signal. The footer control switch signal of a shutdown signal may be generated to control the footer circuitry (e.g., 504, 704) to cause the footer switch 712 to operate. A device or application may generate the shutdown signal to operate the footer circuitry (e.g., 504, 704).

At operation 804, receive the shutdown signal to footer switch(es). The SRAM memory device 100 may receive the shutdown signal at the footer circuitry (e.g., 504, 704).

At operation 806, operate the footer switch(es) to connect to ground based on the shutdown signal received. The footer switch(es) (e.g., 512, 712) of the footer circuitry (e.g., 504, 704) may be operated to connect to ground.

In various embodiments, a footer switch 512 is operated to connect to ground based on the footer switch control signal 514 of a shutdown signal received. The footer switch 512 operating to connect to ground causes the VSSC voltage from the connection to the column slice 310 and the VSSC voltage at electrical connection 518 to the PWELL region of the column slice 310 to both be connected to ground.

In various embodiments, a footer switch 712 is operated to connect to ground based on the footer switch control signal 714 of a shutdown signal received. The footer switch 712 operating to connect to ground causes the VSSC voltage from the connection to the column slice 310 to be connected to ground.

Additionally, the inverse of the shutdown signal is also provided as a first shutdown switch control signal 722 to cause a first transistor of a first shutdown switch 720 to open.

Additionally, the shutdown signal is provided as a second shutdown switch control signal 732 to cause a second transistor of a second shutdown switch 730 to connect to ground and, thus, cause the VSSC voltage from the connection to the PWELL region of the column slice 310 at electrical connection to be connected to ground.

At operation 808, operate the footer switch(s) to open. During a shutdown mode, the footer switch 712 is provided a footer switch control signal 714 operating the footer switch 712 to open. Opening the footer switch 712 makes the VSSC floating and allows the leakage to reduce. In contrast, as an example of operation 806, during a read/write operation, the footer switch control signal 714 is on to close the footer switch 712, which provides ground to VSSC and the PWELL. The footer switch 712 may be operated by the footer switch control signal 714 to change between being turned on and off depending on one or more modes being operated in.

It should be readily appreciated that the embodiments of the systems and apparatuses, described herein may be configured in various additional and alternative manners in addition to those expressly described herein.

### Conclusion

Operations and/or functions of the present disclosure have been described herein, such as in flowcharts. The flowchart blocks support combinations of means for performing the specified operations and/or functions and combinations of operations and/or functions for performing the specified operations and/or functions. It will be understood that one or more blocks of the flowcharts, and combinations of blocks in the flowcharts, can be implemented by special purpose hardware-based computer systems which perform the specified operations and/or functions, or combinations of special purpose hardware with computer instructions.

While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

While operations and/or functions are illustrated in the drawings in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

While this detailed description has set forth some embodiments of the present invention, the appended claims cover other embodiments of the present invention which differ from the described embodiments according to various modifications and improvements.

Within the appended claims, unless the specific term “means for” or “step for” is used within a given claim, it is not intended that the claim be interpreted under 35 U.S.C. § 112, paragraph 6.

1. A SRAM memory device comprising:
one or more memory cores, wherein each memory core comprises a plurality of column slices of bit cells, and wherein each of the column slices of bit cells comprises a plurality of bit cells;
one or more footer switch circuitries, wherein each of the one or more footer switch circuitries is associated with a single column slice of bit cells of the plurality of column slices of bit cells, and wherein each of the one or more footer switch circuitries comprises a footer switch; and
wherein each footer switch comprises a footer transistor, wherein each footer transistor comprises a footer transistor drain, a footer transistor gate, and a footer transistor source; and
wherein each footer circuitries is configured with:
the footer transistor drain of the footer transistor electrically connected to a bit cell source voltage line of a plurality of bit cells and a PWELL region of the associated single column slice of bit cells;
the footer transistor source of the footer transistor electrically connected to ground; and
the footer transistor gate of the footer transistor configured to receive a shutdown signal to operate, in a shutdown mode, the footer transistor as a switch to electrically connect the bit cell source voltage line of the plurality of bit cells and the PWELL region of the associated single column slice of bit cells with ground.

2. The SRAM memory device of claim 1, wherein the SRAM memory, in the shutdown mode, is configured to reduce a forward body bias of the PWELL region of the associated single column slice of bit cells.

3. The SRAM memory device of claim 1, wherein the SRAM memory, in a shutdown mode, is configured for the plurality of bit cells of each column slice to be corrupted and not retain a memory content of each bit cell.

4. The SRAM memory device of claim 1 further comprising one or more header circuitries, wherein each header circuitry is associated with one of the single column slices of bit cells.

5. The SRAM memory device of claim 4, wherein each of one or more header circuitries is comprised of a plurality of transistors configured to operate the SRAM memory device in a functional mode, retention mode, and shutdown mode.

6. The SRAM memory device of claim 1, wherein the plurality of bit cells of each column slice are arranged in a plurality of bit cell rows and a plurality of bit cell columns.

7. The SRAM memory device of claim 1, wherein the one or more memory cores include a first memory core and a second memory core arranged in a butterfly configuration.

8. The SRAM memory device of claim 1, wherein each memory core is comprised of a PWELL region surrounded by an NWELL region.

9. The SRAM memory device of claim 8, wherein the NWELL region is comprised of an external NWELL region and an internal NWELL region, wherein the internal NWELL region is adjacent to a control circuitry.

10. The SRAM memory device of claim 1, wherein the SRAM memory device is in an Internet-of-Things device.

11. A method comprising:
providing a memory device comprising:
one or more memory cores, wherein each memory core comprises a plurality of column slices of bit cells, and wherein each of the column slices of bit cells comprises a plurality of bit cells;
one or more footer switch circuitries, wherein each of the one or more footer switch circuitries is associated with a single column slice of bit cells of the plurality of column slices of bit cells, and wherein each of the one or more footer switch circuitries comprises a footer switch;
wherein each footer switch comprises a footer transistor, wherein each footer transistor comprises a footer transistor drain, a footer transistor gate, and a footer transistor source; and
wherein each footer circuitries is configured with:
the footer transistor drain of the footer transistor electrically connected to a bit cell source voltage line of a plurality of bit cells and a PWELL region of the associated single column slice of bit cells;
the footer transistor source of the footer transistor electrically connected to ground; and
the footer transistor gate of the footer transistor configured to receive a shutdown signal to operate, in a shutdown mode, the footer transistor as a switch to electrically connect the bit cell source voltage line of the plurality of bit cells and the PWELL region of the associated single column slice of bit cells with ground;
receiving a shutdown signal at at least one first footer switch of the plurality of footer switches to operate the at least one first footer switch to connect the bit cell source voltage line of a plurality of bit cells associated with the at least one first footer switch to ground.

12. The method of claim 11 further comprising, in the shutdown mode, reducing a forward body bias of the PWELL region of the associated signal column slice of bit cells.

13. The method of claim 11 further comprising, in the shutdown mode, corrupting the plurality of bit cells of each column slice and not retaining a memory content of each bit cell.

14. The method of claim 11, wherein the memory device further comprises one or more header circuitries, wherein each header circuitry is associated with one of the single column slices of bit cells.

15. The method of claim 14, wherein each of one or more header circuitries is comprised of a plurality of transistors configured to operate the SRAM memory device in a functional mode, retention mode, and shutdown mode.

16. The method of claim 11, wherein the plurality of bit cells of each column slice are arranged in a plurality of bit cell rows and a plurality of bit cell columns.

17. The method of claim 11, wherein the one or more memory cores include a first memory core and a second memory core arranged in a butterfly configuration.

18. The method of claim 11, wherein each memory core is comprised of a PWELL region surrounded by an NWELL region.

19. The method of claim 18, wherein the NWELL region is comprised of an external NWELL region and an internal NWELL region, wherein the internal NWELL region is adjacent to a control circuitry.

20. The method of claim 11, wherein the SRAM device is in an Internet-of-Things device.
